(19) United States
(12) Patent Application Publication
(10) Pub. No.: US 2026/0178806 A1
(43) Pub. Date: Jun. 25, 2026

(54) HIGH-LEVEL SYNTHESIS GENERATION OF ARBITRARY MULTIPLEXER LOGIC

(71) Applicant: Xilinx, Inc., San Jose, CA (US)

(72) Inventors: Liang Ma, Saratoga, CA (US); Alexandre Isoard, San Jose, CA (US); Luciano Lavagno, Berkeley, CA (US); Hem C. Neema, San Jose, CA (US); Ye Yuan, Beijing (CN)

(73) Assignee: Xilinx, Inc., San Jose, CA (US)

(21) Appl. No.: 18/991,525

(22) Filed: Dec. 21, 2024

(51) Int. Cl. G06F 30/327; G06F 30/3312

(52) U.S. Cl. CPC G06F 30/327; G06F 30/3312

(57) ABSTRACT

High-level synthesis generation of multiplexer logic includes generating, using computer hardware, an intermediate representation of a design for an integrated circuit. The design is specified in high-level programming language source code. Selected logic within the intermediate representation is detected by the computer hardware and converted into a sparsemux node. A selected core is chosen from a plurality of cores to implement the sparsemux node. The computer hardware is capable of choosing the selected core based on a label encoding format and a default input of the sparsemux node. A circuit design is generated by the computer hardware. One or more operations of the selected core are scheduled based on a timing model corresponding to the selected core.

### RESERVATION OF RIGHTS IN COPYRIGHTED MATERIAL

A portion of the disclosure of this patent document contains material which is subject to copyright protection. The copyright owner has no objection to the facsimile reproduction by anyone of the patent document or the patent disclosure, as it appears in the Patent and Trademark Office patent file or records, but otherwise reserves all copyright rights whatsoever.

### TECHNICAL FIELD

This disclosure relates to integrated circuits (ICs) and, more particularly, to generating arbitrary multiplexer logic using high-level synthesis.

### BACKGROUND

High-Level Synthesis (HLS) refers to a technology that converts an untimed design into a circuit design that is fully timed. The untimed design is typically specified in high-level programming language source code while the circuit design, being timed or scheduled, is specified in a hardware description language, e.g., as a register transfer level (RTL) description. The circuit design may be physically realized, i.e., implemented, within target hardware such as an integrated circuit (IC).

The Quality-of-Result (QoR) of the implementation of the circuit design within the target hardware often depends on the ability of the HLS tool to recognize particular features of the high-level programming language source code of the untimed design and the ability to map such features onto particular hardware resources available in the target hardware. The QoR may refer to metrics such as the amount of resources of the target hardware consumed by the circuit design and, with respect to the target hardware with the circuit design physically realized therein, the operating speed or frequency of the target hardware, latency of the target hardware, and/or throughput of the target hardware.

The process of converting the untimed design into a fully timed circuit design involves converting the high-level programming language description of the design into an intermediate representation or “IR” where further analysis and optimizations may be performed. Within the IR, “phi” nodes are used to represent multiplexer functionality. An HLS tool, for example, will typically convert a phi node of the IR into a full-multiplexer node or a chain of select nodes within the resulting RTL description.

The handling of phi nodes by the HLS tool often leads to situations in which the estimated timing of the design by the HLS tool differs from the timing estimated by other downstream tools once synthesis is performed and/or the timing that is ultimately achieved for the circuit design as physically realized in the target hardware. Often, the HLS tool is inaccurate and overly pessimistic in the timing estimates provided to users, which can adversely affect the development process. The development process may be difficult to manage and become more likely to produce reduced QoR with respect to the physical realization of the circuit design.

### SUMMARY

In one or more embodiments, a method includes generating, using computer hardware, an intermediate representation of a design for an integrated circuit. The design is specified in high-level programming language source code. The method includes detecting, by the computer hardware, selected logic within the intermediate representation and converting the selected logic into a sparsemux node. The method includes choosing, by the computer hardware, a selected core from a plurality of cores to implement the sparsemux node. The selected core is chosen based on a label encoding format and a default input of the sparsemux node. The method includes generating, by the computer hardware, a circuit design. One or more operations of the selected core are scheduled based on a timing model corresponding to the selected core.

In one or more embodiments, a system includes a computer-readable storage medium having program instructions stored thereon. The system includes a hardware processor capable of executing the program instructions to perform operations. The operations include generating an intermediate representation of a design for an integrated circuit. The design is specified in high-level programming language source code. The operations include detecting selected logic within the intermediate representation and converting the selected logic into a sparsemux node. The operations include choosing a selected core from a plurality of cores to implement the sparsemux node. The selected core is chosen based on a label encoding format and a default input of the sparsemux node. The operations include generating a circuit design. One or more operations of the selected core are scheduled based on a timing model corresponding to the selected core.

In one or more embodiments, a computer program product includes a computer readable storage medium having program instructions embodied therewith. The program instructions are executable by computer hardware, e.g., a hardware processor, to cause the computer hardware to execute operations. The operations include generating an intermediate representation of a design for an integrated circuit. The design is specified in high-level programming language source code. The operations include detecting selected logic within the intermediate representation and converting the selected logic into a sparsemux node. The operations include choosing a selected core from a plurality of cores to implement the sparsemux node. The selected core is chosen based on a label encoding format and a default input of the sparsemux node. The operations include generating a circuit design. One or more operations of the selected core are scheduled based on a timing model corresponding to the selected core.

This Summary section is provided merely to introduce certain concepts and not to identify any key or essential features of the claimed subject matter. Many other features and embodiments of the disclosed technology will be apparent from the accompanying drawings and from the following detailed description.

### BRIEF DESCRIPTION OF THE DRAWINGS

The accompanying drawings show one or more embodiments of the disclosed technology. The drawings, however, should not be construed to be limiting of the inventive arrangements to only the embodiments shown. Various aspects and advantages will become apparent upon review of the following detailed description and upon reference to the drawings.

FIG. 1 illustrates an example framework that is executable by an Electronic Design Automation system in accordance with one or more embodiments of the disclosed technology.

FIG. 2 illustrates a method of high-level synthesis using sparsemux functionality in accordance with one or more embodiments of the disclosed technology.

FIG. 3 illustrates a method of selecting a timing library for use in characterizing a core in accordance with one or more embodiments of the disclosed technology.

FIG. 4 illustrates an example of a data processing system for use with the inventive arrangements in accordance with one or more embodiments of the disclosed technology.

### DETAILED DESCRIPTION

While the disclosure concludes with claims defining novel features, it is believed that the various features described within this disclosure will be better understood from a consideration of the description in conjunction with the drawings. The process(es), machine(s), manufacture(s) and any variations thereof described herein are provided for purposes of illustration. Specific structural and functional details described within this disclosure are not to be interpreted as limiting, but merely as a basis for the claims and as a representative basis for teaching one skilled in the art to variously employ the features described in virtually any appropriately detailed structure. Further, the terms and phrases used within this disclosure are not intended to be limiting, but rather to provide an understandable description of the features described.

This disclosure relates to integrated circuits (ICs) and, more particularly, to generating arbitrary multiplexer logic using high-level synthesis (HLS). In accordance with the inventive arrangements described within this disclosure, methods, systems, and computer-program products are provided that are capable of generating multiplexer logic, e.g., a register-transfer level (RTL) description of multiplexer logic, from an untimed design with greater flexibility than conventional HLS techniques. The inventive arrangements are capable of providing more accurate timing information for the RTL multiplexer logic that is generated. In one or more embodiments, a new operation node is introduced that may be used within the intermediate representation (IR) generated for an untimed design.

The new operation node may be implemented as an IR instruction and referred to herein as a “sparse multiplexer node” or a “sparsemux node.” The sparsemux node may be used to unify and/or simplify the processing performed by an implementation tool such as an HLS compiler when operating on certain IR structures to be implemented using multiplexer circuitry. Though the sparsemux node may be used to represent a variety of different IR structures, an example of an IR structure that may be represented using a sparsemux node is a phi node.

A phi node is a type of IR instruction that is used to merge control flow paths of the untimed design to select a value from one of several possible value sources. The particular value selected by the phi node depends on the control flow path taken to reach the current point in the untimed design. Many HLS tools implement an optimization in which particular logic such as an array partition is represented within the IR by a phi node having a large number of control flow branches. The phi node is often synthesized as a full multiplexer or as a sequence of smaller multiplexers based on scheduling results for the untimed design. The full multiplexer requires significant resources of the target hardware to implement and may implement particular paths that are not used in the target hardware. Further, in cases where timing estimates are inaccurate, so too may the scheduling performed by the HLS compiler thereby rendering the resulting circuit design as realized in target hardware inefficient or inoperable.

In accordance with the inventive arrangements described herein, a sparsemux node may be used in place of, or in lieu of, a phi node within the IR generated for an untimed design. In one or more embodiments, entire portions of IR logic or code, including the phi node, may be represented using a single sparsemux node. The sparsemux node provides various benefits described herein in greater detail below. For example, accurate timing information may be more readily calculated using the sparsemux node. The HLS tool is capable of applying a characterization procedure to the sparsemux node to obtain more accurate timing information for logic created from synthesizing the sparsemux node.

The sparsemux node also unifies the processing of phi nodes. The sparsemux node provides improved syntax that better describes the behavior of a phi node in the resulting RTL generated by the HLS tool. The sparsemux node may be inferred as part of various IR optimization procedures such as, for example, array partitioning, switch elimination, and/or if-conversion. For example, the sparsemux node provides a mechanism by which the input value for each case label need not be provided. Instead, only input values for those case labels of interest, e.g., that are reachable, may be provided. This leads to a simplified circuit design in which improved QoR for the circuit design as physically realized in the target hardware is achieved.

Further aspects of the inventive arrangements are described below with reference to the figures. For purposes of simplicity and clarity of illustration, elements shown in the figures have not necessarily been drawn to scale. For example, the dimensions of some of the elements may be exaggerated relative to other elements for clarity. Further, where considered appropriate, reference numbers are repeated among the figures to indicate corresponding, analogous, or like features.

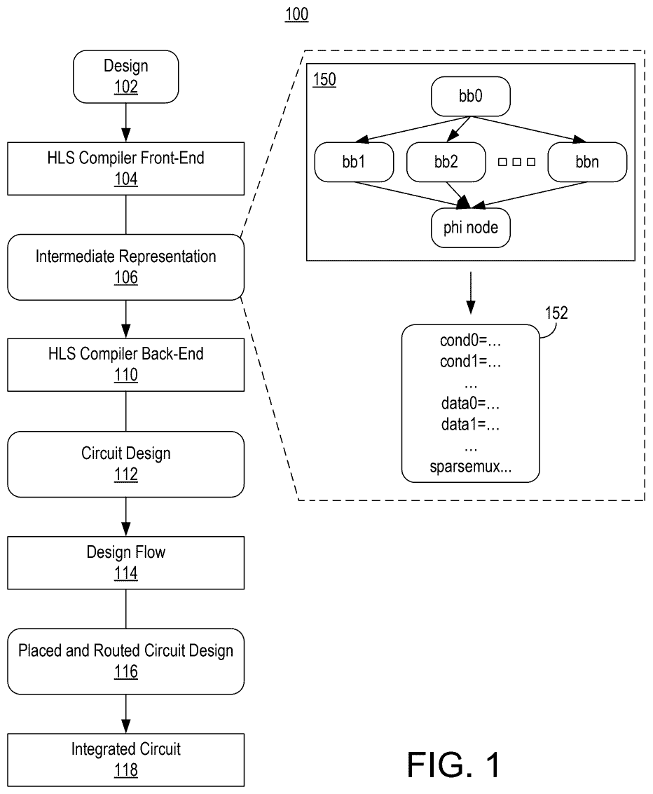

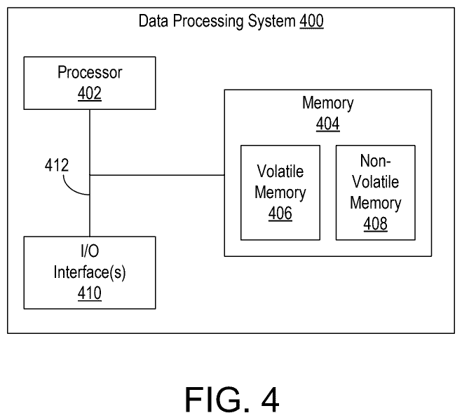

FIG. 1 illustrates an example framework 100 that is executable by an Electronic Design Automation (EDA) system. The EDA system is capable of realizing a user-specified design in hardware. The EDA system may be implemented as a data processing system, e.g., a computer, executing suitable operational software or program code to perform the various operations described within this disclosure. An example of a data processing system that may be used to implement an EDA system and execute framework 100 of FIG. 1 is described in connection with FIG. 4.

In the example of FIG. 1, the EDA system may include an HLS compiler that, when executed, is capable of generating a scheduled version of a design 102 that may be transformed into a hardware description language (HDL) or RTL representation of the design. The HLS compiler may include an HLS compiler front-end 104 and an HLS compiler back-end 110.

In the example, design 102 is provided to HLS compiler front-end 104. Design 102 may be specified as source code. Design 102 may be a user-specified design intended for implementation in target hardware such as a particular IC. The source code may be specified using a high-level programming language. Examples of high-level programming languages include, but are not limited to, C, C++, Python, and OpenCL. Accordingly, design 102 is an untimed high-level specification, e.g., an untimed design.

In general, the HLS compiler transforms design 102 into a fully timed implementation, e.g., circuit design 112. During this transformation, the HLS compiler creates a custom architecture for design 102 to meet particular specification requirements. The architecture generated contains the data path(s), control logic, memory interfaces, and may define how the hardware description language (e.g., RTL) will communicate with systems external to the target hardware. A data path may be formed of a set of storage elements such as (registers, register files, and/or memories), a set of functional units (such as ALUs, multipliers, shifters, and other custom functions), and interconnect elements (such as tristate drivers, multiplexers, and buses). Each component can take one or more clock cycles to execute, can be pipelined, and can have input or output registers.

HLS compiler front-end 104 may include a static analyzer and one or more source code analysis tools. HLS compiler front-end 104 is capable of generating an IR 106 of design 102. In one aspect, IR 106 may be specified as an LLVM IR as is used by compilers to represent source code for further processing. IR 106 may be specified as a control data flow graph (CDFG).

In the example of FIG. 1, selected logic 150 of IR 106 is illustrated that includes a plurality of basic blocks (bb) denoted as illustrated as basic blocks bb0, bb1, bb2, through bbn, where “n” is an integer value greater than one. The term “basic block” means a list of one or more instructions of IR 106 in execution order that have a single-entry point and a single exit point. The list of the instructions form the body portion of the basic block.

In the example, selected logic 150 includes many different control branches and represents a situation in which control flow of design 102 flows from basic block bb0 to the phi node by way of any of the various control paths through basic blocks bb1 through bbn. In the example, the phi node may select a particular value based on the particular control path traversed in reaching the phi node. In other words, the phi node may select a particular value if the control path through basic block bb1 is traversed, a different value if the control path through basic block bb2 is traversed, and a still different value if the control path through basic block bbn is traversed. A different value may be selected for each different path.

As discussed, each phi node may represent certain functionality in design 102 that ultimately may be translated or physically realized as multiplexer circuitry. For example, a phi node may be used to represent program code constructs such as case array partitions, case statements, and IF constructs. In accordance with the inventive arrangements, selected logic 150 may be transformed or replaced in IR 106 as a basic block 152. The selected logic 150 of the CDFG having multiple basic blocks and multiple control paths may be represented as a single basic block 152 having simplified data instructions using the sparsemux node.

In one or more embodiments, HLS compiler front-end is capable of generating IR 106 to include one or more phi nodes and replace the phi node(s) with respective or corresponding sparsemux nodes. In one or more other embodiments, HLS compiler front-end 104 is capable of generating IR 106 using sparsemux nodes in lieu of phi nodes. That is, IR 106 is initially generated to include sparsemux nodes without first including any phi nodes therein. In either case, the sparsemux nodes are used in IR 106 in lieu of phi nodes.

HLS compiler back-end 110 is capable of translating IR 106 into a circuit design 112. Circuit design 112 may be specified as an RTL description. For example, circuit design 112 may be specified in a hardware description language such as Verilog or VHDL. In generating circuit design 112, HLS compiler back-end 110 is capable of scheduling IR 106. HLS compiler back-end 110 is capable of performing operations such as scheduling and/or binding of IR 106 to generate circuit design 112.

Continuing with the example of FIG. 1, circuit design 112 may be processed through a design flow 114. Design flow 114 may include a synthesis process, a placement process, and a routing process. Design flow 114 may generate a placed and routed circuit design 116, as scheduled. In the example, the placed and routed circuit design 116 may be specified in any of a variety of different formats including, for example, as configuration data or a configuration bitstream, that may be loaded into an IC such as IC 118 thereby physically implementing, e.g., realizing, design 102 in IC 118.

IC 118 may be implemented as any of a variety of different types of ICs including, but not limited to, an Application-Specific IC, a System-on-Chip, a programmable IC (e.g., an IC including at least some programmable circuitry such as a field-programmable gate array, where programmable logic is a type of programable circuitry), or the like.

In the example of FIG. 1, HLS compiler back-end 110 is well suited for scheduling and estimating the timing of data path instructions. HLS compiler back-end 110 does not perform, or performs little, optimization of instructions across basic blocks in a CDFG such as IR 106. By comparison, HLS compiler front-end 104 is well suited to performing predicate analysis and CDFG transformations. The example of FIG. 1 illustrates that usage of the sparsemux node enables HLS compiler front-end 104 and HLS compiler back-end 110 to cooperate more effectively. That is, HLS compiler front-end 104 effectively transforms CDFG constructs involving control paths for a phi node into a sparsemux node that includes data path instructions (e.g., fewer data path instructions) thereby allowing HLS compiler back-end 110 to perform scheduling more easily and accurately as described herein in greater detail below.

Example 1 below illustrates a reflow intrinsic of a sparsemux node, e.g., an IR sparsemux instruction, that may be created in IR 106. As generally known, an intrinsic refers to a built-in function to the compiler (e.g., HLS compiler front-end 104). Example 1 illustrates a format that may be used by HLS compiler front-end 104.

### Example 1

$$\% res = call float @ llvm . fpga . sparse . mux . float . i 3 ( i 30 , float \% c , i 32 , float \% c , i 34 , float \% c , i 35 , float \% c , i 36 , float \% c , i 37 , float \% c )$$

Referring to Example 1, HLS compiler front-end 104 is capable of analyzing design 102 and detecting selected logic expressed in IR and converting the selected logic into a sparsemux node. The sparsemux node has four different arguments. The arguments are a selector, a default value, one or more case labels, and one or more case values.

The selector is a single-static assignment (SSA) value that dynamically determines the particular case to select. The default value is an SSA value that corresponds to the default case result. If no other case is selected, the sparsemux node selects the default value and returns that value as the default case result. The default value may be undefined, which may be denoted as “undef.” A case label is the literal constant that corresponds to the case. The case is selected if and only if the value of the selector is equal to case label. The case value is an SSA value that corresponds to the case result. If, for example, a particular case is selected, the sparsemux node returns the case value for the case as the result.

A sparsemux node has the following properties. The first argument is the selector. In Example 1, the selector is “% sel.” The second argument is the default value. In Example 1, the default value is “% def” and is a floating-point value. The remaining arguments include an even number of arguments that alternate between a case label followed by a case value. That is, one or more pairs of <case label, case value> follow. In Example 1, the values “0,” “2,” “4,” “5,” “6,” and “7” are case labels and the corresponding case values are “% a,” “% b,” and “% c.” An example of a case label-case value pair is “0, % a.” In the example, each case value is specified as a floating-point value.

A sparsemux node may have one or more additional requirements. These may include the selector and each case label being of the same type. There is no implicit zext/sext/trunc operations. Further, the selector and each case label must be of the integer type. As generally understood, within LLVM, “zext” indicates that the parameter should be zero extended just before a call to this function. “Sext” indicates that the parameter should be sign extended just before a call to this function. “Trunc” truncates high order bits in a value and converts the remaining bits to ty2 type. In addition, the return type of the intrinsic (e.g., the case values), the type of the default value, and the type of each case value are the same, e.g., there is no implicit zext/sext/trunc operation. Further, each case label of the sparsemux node is a unique constant and cannot be undefined. The order of the cases is irrelevant to support parallelism.

In using a sparsemux node, only input values for those cases of interest are necessary rather than defining each possible case when interpreting a phi node as a full multiplexer implementation. For example, case labels corresponding to “1” and “3” are not included in Example 1 as these cases are not of interest. The elimination of cases of no interest can reduce the size of the circuit design as realized in the target hardware as excluded paths (e.g., “1” and “3”) are not physically implemented unlike in the case of a full multiplexer implementation for a phi node.

In one or more embodiments, the sparsemux node may take several forms through the HLS flow illustrated in FIG. 1 between HLS compiler front-end 104 and HLS compiler back-end 110. The different forms of sparsemux nodes may use different syntaxes. For example, while a sparsemux node may be expressed as illustrated in Example 1 with HLS compiler front-end 104, another syntax may be used for another portion of the HLS compiler such as HLS compiler back-end 110. For example, HLS compiler back-end 110 may use a sparsemux node having a syntax illustrated in Example 2 below. In Example 2, the selector is the last argument and the default value is the second to last argument.

### Example 2

$$\% res = call float @ \_ssdm \_op \_SparseMux . ap\_auto \text{.6} f 32. f 32. i 3 ( i 30 , float \% a , i 32 , float \% b , i 34 , float \% c , i 35 , float \% c , i 36 , float \% c , i 37 , float \% c , float \% def , i 3 \% sel )$$

In one or more embodiments, HLS compiler front-end 104 generates a sparsemux node having the syntax illustrated in Example 1. Subsequently, the syntax of the sparsemux node is modified by HLS compiler front-end 104 or HLS compiler back-end 110 to that illustrated in Example 2 for use by HLS compiler back-end 110. In one or more other embodiments, HLS compiler front-end 104 may be configured to generate the sparsemux node in using the syntax illustrated in Example 2 rather than the syntax of Example 1.

As part of generating RTL from IR 106, in one or more embodiments, HLL compiler back-end 110 is capable of representing a sparsemux node using the case statement. Example 3 below illustrates a case statement generated by HLS compiler back-end 110 for a detected sparsemux node corresponding to Example 2.

### Example 3

```
always @ (*) begin
case (sel)
  CASE0 : dout = din0;
  CASE1 : dout = din1;
  CASE2 : dout = din2;
  CASE3 : dout = din3;
  CASE4 : dout = din4;
  CASE5 : dout = din5;
  default : dout = def;
endcase
end
```

In the RTL of Example 3, the behavioral description of the case statement represents the functionality of the sparsemux node of Example 2. In Example 3, the inputs and the output are registered according to the scheduling results. The values of CASE<n> are constant and may be assigned via the parameters in a Verilog implementation during the instance instantiation or via generics in a VHDL implementation.

In one or more embodiments, the RTL of Example 3 may be stored as a template in which the number of cases “n” will adjust based on the number of case labels. For example, HLS compiler back-end 110 is capable of generating the RTL template, adjusting the number of cases to correspond to the number of case labels, and mapping case labels 0, 2, 4, 5, 6, and 7 to CASE0, CASE1, CASE2, CASE3, CASE4, and CASE5, respectively. Similarly, HLS compiler back-end 110 maps the case values of % a, % b, % c, % c, % c, and % c to din0, din1, din2, din3, din4, and din5, respectively. Any undefined case labels received are assigned to the default “def.”

In one or more embodiments, a high-level programming language (HLPL) sparsemux function may be made available for use within untimed designs such as design 102. For example, the HLPL sparsemux function may be one specified in C/C++ as a built-in or intrinsic function of the HLS compiler. The HLPL sparsemux function is differentiated from an IR instruction such as the sparsemux node. In cases where HLS compiler front-end 104 detects the HLPL sparsemux function in design 102, HLS compiler front-end 104 may translate the HLPL sparsemux function into a sparsemux node within IR 106. The HLPL sparsemux function may be directly mapped as sparsemux in RTL that is generated (e.g., circuit design 112). For example, the HLPL sparsemux function directly maps to the sparsemux node, which directly maps to particular RTL implementation thereof. The HLPL sparsemux function allows developers to customize design 102 and exert fine control over sparsemux functionality (e.g., the generation of RTL for such structures) with particular labels and inputs being explicitly defined rather than detected or inferred by the HLS compiler. Timing information also may be added according to schedule results. For example, registers may be added to the RTL to make the operations meet required latency.

Example 4 illustrates an HLPL sparsemux function that may be detected by HLS compiler front-end 104 within design 102.

### Example 4

void__fpga_sparse_mux(T*ret, int sel, const T*def, int lbl0, const T*val0, int lbl1, const T*val1, . . . , int lblN, const T*valN)

In Example 4, the HLPL sparsemux function has the arguments “sel” as the selector, “def” as the default value, one or more case labels shown as “val0,” “val1,” through “valN,” and one or more case values “Ibl0,” “Ibl1,” through “lblN.” As illustrated the case labels and case values are specified as pairs.

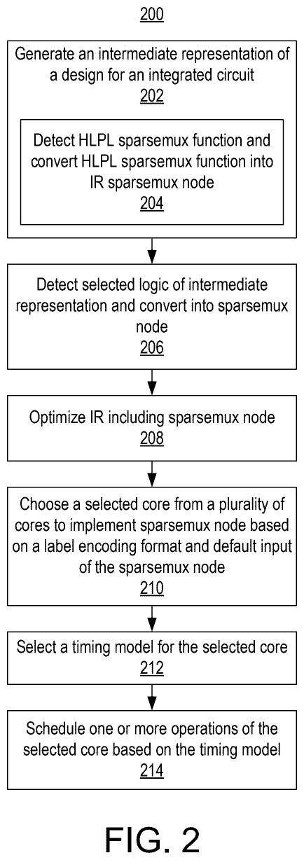

FIG. 2 illustrates a method 200 of HLS using sparsemux functionality in accordance with one or more embodiments of the disclosed technology. Method 200 may be implemented by a data processing system as described herein executing a framework such as framework 100 in the example of FIG. 1. Method 200 may begin in a state where design 102, being specified in HLPL source code such as C/C++ is provided as an input to an EDA system including an HLS compiler.

In block 202, HLS compiler front-end 104 is capable of generating an intermediate representation, e.g., IR 106, of design 102 for an IC. Block 202, as performed by HLS compiler front-end 104, may include one or more other operations illustrated as constituent blocks of block 202. For example, in block 204, HLS compiler front-end 104 is capable of detecting an HLPL sparsemux function in design 102 and converting the HLPL sparsemux function into a sparsemux node. Appreciably, in the case where design 102 includes multiple HLPL sparsemux functions, HLS compiler front-end 104 may convert each to a sparsemux node using the particular arguments in the sparsemux node specified in the corresponding HLPL sparsemux function. In the case where design 102 includes no HLPL sparsemux functions, HLS compiler front-end 104 may skip block 206.

In block 206, HLS compiler front-end 104 is capable of detecting selected logic of IR 106 and convert the selected logic, as detected, into an IR sparsemux node. For example, HLS compiler front-end 104 is capable of analyzing IR 106 and detecting instances of the selected logic specified as particular IR structure(s) within IR 106. Each of IR structure corresponding to a selected logic is one that may be implemented using multiplexer circuitry in the target hardware. Examples of selected logic, or IR structures, that may be detected and represented as a sparsemux node may include, but are not limited to, an array that is partitioned, a switch statement in design 102 that may be represented in IR 106 as a switch-case structure, and an IF structure from design 102. In this example, the IF structure may include IF, IF-THEN, and/or IF-THEN-ELSE structures.

For purposes of illustration, an array partition is a transformation operation implemented by HLS compiler front-end 104 that breaks an array into multiple sub-arrays called banks. The number of banks (e.g., partitions) into which the array is subdivided may be explicitly specified by a user or may be automatically inferred by the implementation tool(s). Each bank corresponds to a portion of the original array. It may be the case, however, that the design (e.g., the program) as written does not access all the locations in the array, which may lead to some partitions or banks not being used. In general, each access of the array may be routed to a single bank thereby allowing other accesses of the array to occur in parallel if such accesses are routed to different banks. The array partition transformation can significantly increase the effective bandwidth of an array albeit at the cost of increased routing logic.

Within conventional HLS compilers, the routing logic of a partitioned array is typically specified in IR as a switch instruction with multiple case basic blocks, e.g., one case basic block for each bank. This IR structure is expensive to carry through the entire compilation flow as it is lengthy and complex. The IR structure can significantly increase runtime (e.g., compile time) of the HLS compiler.

In the case of accesses without side effects, such as load, HLS compiler front-end 104 is capable of replacing the IR structure of a partitioned array (e.g., a switch instruction with multiple case basic blocks) with a multiplexer that may be represented in the IR as a sparsemux node. Use of the sparsemux node can significantly reduce runtime of the HLS compiler and result in a more efficient hardware implementation of design 102 because HLS compiler front-end 104 is able to trim-out banks of the partitioned array that are known to be unreachable (e.g., unused) during operation of the circuit design as realized in the target hardware. HLS compiler front-end 104 may detect particular banks that are unreachable based on a static analysis of IR 106.

As an illustrative and non-limiting example, consider Example 5 below illustrating IR generated from HLPL instructions such as “A[idx]” that implement an address computation and load into a 48-element array.

### Example 5

$$\% A\_addr = getelementptr [ 48 \times float ] , {[ 48 \times float ]}^{*} \% A , i 64 \; 0 , i 64 \% idx$$

$$\% A\_val = load float , {float}^{*} \% A\_addr$$

HLS compiler front-end 104 is capable of rewriting the code of Example 5 as the code illustrated in Example 6 below where the array is partitioned into four banks. For example, the IR may include an instruction such as “call void @_ssdm_ArrayPartition ([48×float]* % A, i32 4, “cyclic”)” that indicates partitioning of the array into 4 banks.

### Example 6

$$\% bidx = urem i 64 \% idx , i 64 \; 4$$

$$\% lidx = udiv i 64 \% idx , i 64 \; 4$$

$$\% A\_addr \_ 0 = getelementptr [ 12 \times float ] , {[ 12 \times float ]}^{*} \% A\_ 0 , i 64 \; 0 , i 64 \% lidx$$

$$\% A\_addr \_ 1 = getelementptr [ 12 \times float ] , {[ 12 \times float ]}^{*} \% A\_ 1 , i 64 \; 0 , i 64 \% lidx$$

$$\% A\_addr \_ 2 = getelementptr [ 12 \times float ] , {[ 12 \times float ]}^{*} \% A\_ 2 , i 64 \; 0 , i 64 \% lidx$$

$$\% A\_addr \_ 3 = getelementptr [ 12 \times float ] , {[ 12 \times float ]}^{*} \% A\_ 3 , i 64 \; 0 , i 64 \% lidx$$

$$\% A\_val \_ 0 = load float , {float}^{*} \% A\_addr \_ 0$$

$$\% A\_val \_ 1 = load float , {float}^{*} \% A\_addr \_ 1$$

$$\% A\_val \_ 2 = load float , {float}^{*} \% A\_addr \_ 2$$

$$\% A\_val \_ 3 = load float , {float}^{*} \% A\_addr \_ 3$$

$$\% A\_val = call float @ llvm . fpga . sprase . mux ( i 64 \% bidx , float undef , i 64 \; 0 , float \% A\_val \_ 0 , i 64 \; 1 , float \% A\_val \_ 1 , i 64 \; 2 , float \% A\_val \_ 2 , i 64 \; 3 , float \% A\_val \_ 3 )$$

In one or more embodiments, HLS compiler front-end 104 is capable of removing IR instructions (e.g., optimize IR in block 208) that correspond to unreachable array partitions. Example 7 below illustrates an optimization of Example 6 as performed by HLS compiler front-end 104 in which those IR instructions corresponding to unreachable banks have been removed.

### Example 7

$$5 bidx = urem i 64 \% idx , i 64 \; 4$$

$$\% lidx = udiv i 64 \% idx , i 64 \; 4$$

$$\% A\_addr \_ 1 = getelementptr [ 12 \times float ] , {[ 12 \times float ]}^{*} \% A\_ 1 , i 64 \; 0 , i 64 \% lidx$$

$$\% A\_addr \_ 3 = getelementptr [ 12 \times float ] , {[ 12 \times float ]}^{*} \% A\_ 3 , i 64 \; 0 , i 64 \% lidx$$

$$\% A\_val \_ 1 = load float , {float}^{*} \% A\_addr \_ 1$$

$$\% A\_val \_ 3 = load float , {float}^{*} \% A\_addr \_ 3$$

$$\% A\_val = call float @ llvm . fpga . sprase . mux ( i 64 \% bidx , float undef , i 64 \; 1 , float \% A\_val \_ 1 , i 64 \; 3 , float \% A\_val \_ 3$$

In Example 7, HLS compiler front-end 104 has performed analysis, e.g., static analysis, and detected that one or more banks of the partitioned array are not ever accessed. In this case, banks 0 and 2 are not accessed. The design only accesses odd banks, e.g., 1 and 3. Accordingly, IR code pertaining to unused banks 0 and 2 has been removed, thereby reducing the size of the IR structure. In Example 6, “undef” is used as the default value. Unreachable banks become irrelevant.

The reduced complexity and trimming of unused pathways facilitated by the sparsemux node also results in improved QoR in the RTL that is generated and the physical realization of the circuit design in the target hardware. For example, routing resources that would otherwise be implemented and never used are not implemented in circuitry, which reduces complexity of the circuit design (e.g., reduces runtime of the implementation tools) and reduces congestion or competition for routing resources.

Without using a sparsemux node, the IR would use a “mux” node which requires all possible inputs even if the input is undefined and, as such, not relevant. This means that the mux node accounts for all possible combinations, e.g., enables each partition. This often results in very dense and wide (e.g., large) multiplexers with many unused paths. An example of a mux node is “% A_val=call float @llvm.fpga.mux (i64% bidx, float undef, float undef, float % A_val_1, float undef, float % A_val_3).” The use of the sparsemux node provides a clearer and easier to handle syntax for the HLS compiler to perform optimizations than is the case with phi node structures. The syntax of a sparsemux node is amenable to optimization operations such as trimming. Further, as the sparsemux node is IR and closer to the original source code of design 102, optimizations may be performed more readily than by attempting to optimize over the more complex semantics of RTL.

In one or more other embodiments, an array partition may produce a switch-case+phi node structure. This structure, which is similar to Example 8 below, also may be optimized by using a sparsemux node.

Example 8 illustrates a switch-case IR structure that may be included in IR 106 and represented using a sparsemux node. For purposes of discussion, HLS compiler front-end 104 may generate a switch-case IR structure from a switch statement detected in design 102. Accordingly, HLS compiler front-end 104 is capable of detecting the switch-case IR structure, e.g., as illustrated in Example 8 below.

### Example 8

```
switch i3 %sel, label %default [ i3 0, label %case0
    i3 2, label %case2
    i3 4, label %case4
    i3 5, label %case5
    i3 6, label %case6
    i3 7, label %case7 ]
case0:
  br label %exit
case2:
  br label %exit
case4:
  br label %exit
case5:
  br label %exit
case6:
  br label %exit
case7:
  br label %exit
default:
  br label %exit
exit:
%res = phi float [ %a, %case0 ], [ %b, %case2 ], [ %c, %case4 ],
[ %c, %case5 ], [ %c, %case6 ], [ %c, %case7 ], [ %def, %default ]
```

In one or more embodiments, HLS compiler front-end 104 is capable of performing an optimization that eliminates or removes empty switch structures. Typically, a switch-case IR structure is generated to execute different cases under different conditions. Optimization operations may successfully empty one or more cases of content such that the only remaining purpose of the switch-case IR structure is to produce a value that depends on the particular case (e.g., path) taken. Example 9 below illustrates an optimization of Example 8 as performed by HLS compiler front-end 104. In Example 9, HLS compiler front-end 104 replaces the switch-case IR instructions of Example 8 with a sparsemux node.

### Example 9

$$\% res = call float @ \_ssdm \_op \_SparseMux . ap\_auto \text{.6} f 32. f 32. i 3 ( i 30 , float \% a , i 32 , float \% b , i 34 , float \% c , i 35 , float \% c , i 36 , float \% c , i 37 , float \% c , float \% def , i 3 \% sel )$$

Example 8 is difficult to optimize because the value assigned by the phi node is dependent on the path taken to reach the phi node. By converting the IR structure into the sparsemux node of Example 9, the value assignment is achieved with less complexity and fewer basic blocks.

Example 10 below illustrates an IR representation of an IF construct from design 102. In one or more embodiments, HLS compiler front-end 104 is capable of performing an IF-conversion in which any amount of control can be folded into a single sparsemux node. The control may involve, for example, one or more switch-cases and one or more IF structures (e.g., IF, IF-THEN, and/or IF-THEN-ELSE). The switch-case and IF structures may be nested arbitrarily and to an arbitrary depth. In representing such nested structures, HLS compiler front-end 104 ensures that each of the switch-case and IF structures lead to an empty basic block such that the only purpose of the branching is to make a final selection based on which path is taken.

### Example 10

```
%cond = icmp lte i64 %idx, 0
  br i1 %cond, label %then, label %else
then:
  switch i2 %x, label %case_x_def [ i2 0, label %case_x_0,
    i2 1, label %case_x_1,
    i2 −2, label %case_x_2 ]
case_x_0:
  br label %exit
case_x_1:
  br label %exit
case_x_2:
  br label %exit
case_x_def:
  br label %exit
else:
  switch i8 %y, label %case_y_def [ i8 1, label %case_y_p,
    i8 −1, label %case_y_n ]
case_y_p:
  br label %exit
case_y_n:
  br label %exit
case_y_def:
  br label %exit
exit:
%res = phi float [ %a, %case_x_0 ], [ %b, %case_x_1 ], [ %c, %case_x_2 ], [
%def, %case_x_def ], [ %d, %case_y_p ], [ %e, %case_y_n ], [ undef,
%case_y_def ]
```

In Example 10, there are two switch-cases with each being based on a different selector. The switch-cases are nested inside an IF-THEN-ELSE structure, which itself has a different selector. In this case, the control may not be represented using different values of a single selector. Accordingly, in this example, a different implementation of the sparsemux node may be used that utilizes one-hot encoding. More particularly, a one-hot encoding of the path taken is used in cases where there is more than one selector. Each path, for example, computes its own individual Boolean condition that may be concatenated together with the other paths. The concatenation generated may be used as the one-hot encoding to implement a single sparsemux node that makes the selection.

Example 11 below illustrates a sparsemux node implementation of Example 10 using one-hot encoding.

### Example 11

$$\% cond = icmp ite i 64 \% idx , 0$$

$$\% ncond = xor i 1 \% cond , true$$

$$\% cond\_x \_ 0 = icmp eq i 2 \% x , 0$$

$$\% cond\_x \_ 1 = icmp eq i 2 \% x , 1$$

$$\% cond\_x \_ 2 = icmp eq i 2 \% x , 2$$

$$\% cond\_y \_p = icmp eq i 8 \% y , 1$$

$$\% cond\_y \_n = icmp eq i 8 \% y , - 1$$

$$\% csel\_ 0 = and i 1 \% cond , \% cond\_x \_ 0$$

$$\% csel\_ 1 = and i 1 \% cond , \% cond\_x \_ 1$$

$$\% csel\_ 2 = and i 1 \% cond , \% cond\_x \_ 2$$

$$\% csel\_ 3 = and i 1 \% cond , \% cond\_y \_p$$

$$\% csel\_ 4 = and i 1 \% cond , \% cond\_y \_n$$

$$\% csel = call i 5 @ \_ssdm \_op \_BitConcatenate . i 5 ( i 1 \% csel\_ 4 , i 1 \% csel\_ 3 , i 1 \% csel\_ 2 , i 1 \% csel\_ 1 , i 1 \% csel\_ 0 )$$

In the example of FIG. 11, HLS compiler front-end 104 computes a concatenation of “i1% csel_4, i1% csel_3, i1% csel_2, i1% csel_1, i1% csel_0” into a single variable “% csel.” The computed condition “% csel” is the concatenation of each basic block. The instructions corresponding to these basic blocks are computationally efficient or inexpensive to compute. The variable “% csel” specifies the one-hot encoding which may be used by a single sparsemux node. In the example of FIG. 11, the label for each case is a power of two because at most one bit is high in the one-hot encoding.

In block 208, HLS compiler front-end 104 is capable of optimizing IR 106 which may include optimizing one or more of the sparsemux nodes. For example, HLS compiler front-end 104 is capable of performing the various optimizations described herein in connection with Examples 6 and 7; Examples 8 and 9; and Examples 10 and 11.

Blocks 210 and 212 illustrate various operations performed by HLS compiler back-end 110 that generate timing information used in scheduling circuit design 112. In block 210, HLS compiler back-end 110, in generating circuit design 112 from IR 106, is capable of choosing a selected core from a plurality of cores to implement the sparsemux node. In one or more embodiments, HLS compiler back-end 110 selects a particular core, e.g., an RTL core, for a given sparsemux node based on the encoding format of the labels (e.g., also referred to as the label encoding pattern) of the sparsemux node and based on the default input (e.g., typically a variable value) of the sparsemux node.

To schedule circuit design 112 into correct time slots, HLS compiler back-end 110 must calculate timing information, e.g., delay and latency information, for the sparsemux node. In one or more embodiments, the number of inputs, the data bit width, and the address (i.e., the selection) bit width influence the timing of the hardware implementation of the sparsemux node. These features are represented as integers. Other information such as the label encoding pattern and the behavior of the default value also influence the timing of the hardware implementation of the sparsemux node.

From the foregoing examples, the label encoding pattern may be characterized as binary as in the case of an array partition optimization or as one-hot encoding as may be used for many phi nodes. Behavior of the default value may be characterized as a constant or as a variable (e.g., in switch-case IR structures) or be left as a “don't care.” Based on the label encoding pattern and the default value, HLS compiler back-end 110 is capable of selecting a particular core.

Table 1 below illustrates four example cores and the particular conditions that would cause HLS compiler back-end 110 (e.g., a scheduler of HLS compiler back-end 110) to select each respective core for a given sparsemux node. That is, in response to detecting the data in the patterns column for a given sparsemux node, HLS compiler back-end 110 selects the core of the same row to implement that sparsemux node.

TABLE 1

| ID | Core Name | Patterns |
|---|---|---|
| 0 | SparseMux_Binary_dontCare | Binary encoding |
| | | Don't care default value |
| 1 | SparseMux_oneHot_dontCare | One-hot encoding |
| | | Don't care default value |
| 2 | SparseMux_Binary_realDefault | Binary encoding |
| | | Default input |
| 3 | SparseMux_oneHot_realDefault | One-hot encoding |
| | | Default input |

The scheduler is capable of choosing the core to be used to implement a given sparsemux node based on the detected patterns of the sparsemux node. The selected core may be used to estimate timing features. Further, the scheduler is capable of configuring the selected core with other features and scheduling the sparsemux operation accordingly.

In block 212, HLS compiler back-end 110 is capable of selecting a timing model for the core selected in block 210. The timing model is used to schedule the core selected in block 210 for the sparsemux node.

In one or more embodiments, in the case where the selected core uses one-hot encoding, HLS compiler back-end 110 is capable of selecting a timing model for the selected core based on the integer value for the number of inputs, the data bit width, and the address bit width as discussed in block 210. For example, HLS compiler back-end 110 is capable of categorizing each of the three features according to ranges, with each combination of the three features being associated with a particular timing model.

For purposes of illustration, consider the example sparsemux node illustrated in Example 12 below.

### Example 12

$$\% res = call float @ \_ssdm \_op \_SpareMux . ap\_auto \text{.6} f 32. i 5 ( i 51 , float \% a , i 52 , float \% b , i 54 , float \% c , i 58 , float \% d , i 5 \; 16 , float \% e , i 50 , float \% def , float undef , i 5 \% csel )$$

In Example 12, the sparsemux node includes labels, inputs, default input, and address. Table 2 illustrates these features as extracted from Example 12.

TABLE 2

| | | Value in | Feature category |
|---|---|---|---|
| Feature List | Type | Example 12 | value |
| Input data | Integer | 32 bits (float) | 2 (assume 32-bit) |
| bit width | | | |
| Address (selector | Integer | 5 bits (i5) | 0 (assume 8-bit) |
| bit width) | | | |
| Number of inputs | Integer | 6 | 0 assume 8 inputs) |
| Label patterns | — | — | — |
| Has Default input | Boolean | Yes | Used to choose |
| Is one-hot encoding | Boolean | Yes | cores |

Table 3 below illustrates an example mapping of the different category identifiers (IDs) from Table 2 in the feature category value column to different ranges.

TABLE 3

| Category ID | Range | Characterization Library |
|---|---|---|
| 0 | (0, 8] | Use 8 for characterization |
| 1 | (8, 16] | Use 16 for characterization |
| 2 | (16, 32] | Use 32 for characterization |
| 3 | (32, 64] | Use 64 for characterization |

Table 3 may include additional entries depending on the number of timing models being considered for the various cores. For each category, the timing of the sparsemux node with the largest integer value in the range is used as the category timing. In the case of a core with one-hot encoding, timing characterization is straightforward as the case labels are limited to a given address bit width. For the first three integer features, e.g., input data bit width, address bit width, and number of inputs, those integer features are mapped to category IDs using Table 3 to form a feature vector of [2, 0, 0] in this example. In general, the difference in timing of the sparsemux node within the same category ID was found to be small enough so as to be neglected. The sparsemux node is labeled with the feature vector, which may be used to query a characterization (e.g., timing) library. This technique reduces the size of the characterization library that is needed thereby significantly reducing runtime as all possible combinations of the integer features need not be considered. The characterization library will include a timing model for each possible feature vector, for example as opposed to a timing model for each possible combination of values (prior to mapping to category IDs).

Timing characterization of binary encoding is more complex than the one-hot encoding example described above in that the number of inputs and label values of the sparsemux node may be very large. In one or more embodiments, the complexity of timing characterization for binary encoding is handled through the creation of multiple, different timing libraries that may be used to characterize timing of the cores that utilize binary encoding. The timing libraries used for characterizing cores utilizing binary encoding are distinct from the timing library described above that is used to characterize cores that utilize one-hot encoding.

The timing libraries may include a linear timing library, a variable timing library, and a full-case timing library. Each timing library may provide timing information for different scenarios. The linear timing library includes timing information for cases where the case labels of the sparsemux node are linear. This means that the sparsemux node has N−1 case labels that start from zero and increment by one to N−1, where “N” is the number of inputs of the sparsemux node. By implementing a timing library for this configuration of a sparsemux node, the timing library specifies more accurate timing information (e.g., delay and/or latency) than other libraries. The increased accuracy, however, is only available for the particular case scenario described.

The variable timing library includes timing information determined by characterizing the sparsemux node by using the variable case labels in the RTL to simulate the worst scenarios. Further, the “parallel_mux” attribute is added to the node so that synthesis tools attempt to apply optimizations to the node. The variable timing library is useful because the timing library is capable of providing timing information for all or any sparsemux node with any number of inputs and any address bit-width. The timing information specified in the variable timing library, however, is typically more pessimistic (e.g., worse) than the real delay/latency ultimately realized in the target hardware.

The full-case timing library includes timing information for sparsemux nodes that have a small address bit-width. For example, the full-case library may include timing information for IR sparsemux nodes that have up to an 8-bit address bit-width. In general, the timing information from the full-case library is more optimistic than that of a full-multiplexer with the same address bit width. The full-case timing library provides timing information that is more realistic but is only available for relatively small sparsemux nodes.

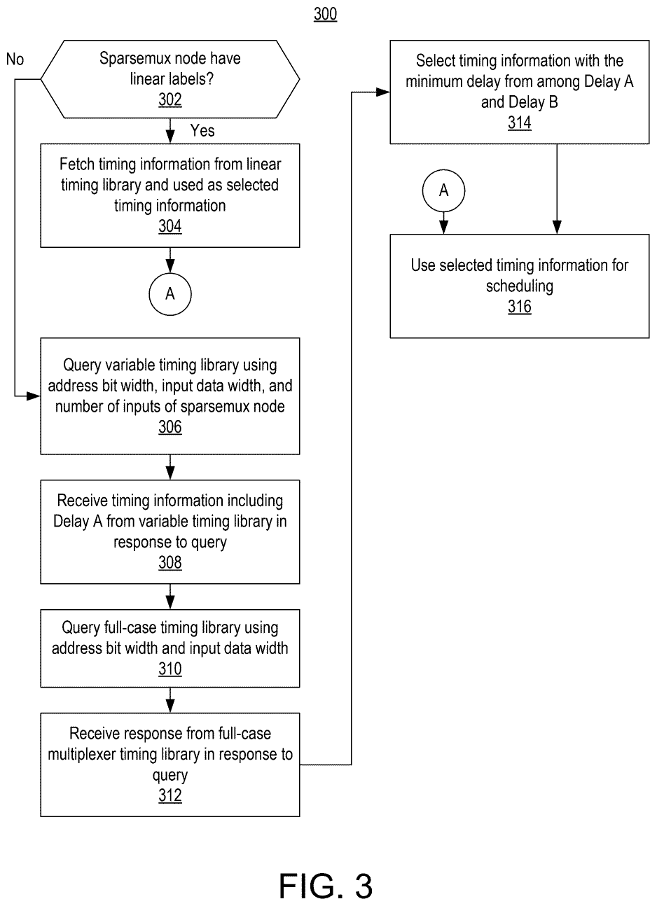

FIG. 3 illustrates a method 300 of selecting a timing library for use in characterizing a core that uses a binary label encoding pattern in accordance with one or more embodiments of the disclosed technology. Method 300 may be used to implement block 212 of FIG. 2 for a core that is selected that uses a binary label encoding pattern (e.g., binary encoding as specified in the Pattern column of Table 1). Method 300 illustrates an example technique for choosing which of the various timing libraries (e.g., the linear, variable, and full-case timing libraries) to choose for obtaining timing information for scheduling the selected core implementation of the sparsemux node that is included in the circuit design.

In block 302, HLS compiler back-end 110 is capable of detecting whether the sparsemux node has linear labels. The sparsemux node has linear labels in the case where the sparsemux node has N−1 case labels that start from zero and increment by one to N−1, where “N” is the number of inputs of the sparsemux node. In response to detecting that the sparsemux node has linear labels, method 300 continues to block 304. In response to detecting that the IR sparsemux node does not have linear labels (e.g., has non-linear labels), method 300 continues to block 306.

In block 304, HLS compiler back-end 110 is capable of fetching timing information from the linear timing library. For example, HLS compiler back-end 110 is capable of querying the linear timing library using the number of inputs as a query parameter and receiving a response to the query. The response specifies timing information, e.g., delay, that is used as the selected timing information in later operations. After block 304, method 300 continues to block 316.

Continuing with block 306 in the case where the sparsemux node has non-linear labels, different timing models are utilized. In block 306, HLS compiler back-end 110 is capable of querying the variable timing library using address bit width, input data width, and number of inputs of the sparsemux node as query parameters. In block 308, HLS compiler back-end 110 is capable of receiving a response from the variable timing library specifying timing information. The timing information may include delay and latency values. For purposes of illustration, the delay of the timing information received from the variable timing library is referred to as Delay A.

In block 310, HLS compiler back-end 110 is capable of querying the full-case timing library using the address bit width and the input data width as query parameters. In block 312, HLS compiler back-end 110 is capable of receiving a response from the full-case timing library. In one or more embodiments, the full-case timing library contains timing information for a limited number of cases. For some queries, given the parameters specified, the full-case library may not include timing information and return a null value or other indication that the library lacks the requested timing information. Accordingly, the response received from the full-case timing library may specify timing information or indicate that no timing information exists in the full-case timing library that meets or corresponds to the query parameters specified. The timing information may include delay and latency values. For purposes of illustration, the delay of the timing information received from the full-case timing library is referred to as Delay B. In the case where the response indicates that the full-case timing library includes no timing information for the specified query parameters, HLS compiler back-end 110 is capable of assigning “inf” to Delay B representing a large or infinite delay value.

In block 314, method 300 has traversed a path in which both the variable timing library and the full-case timing library have been queried as the sparsemux node has non-linear labels. Accordingly, in block 314, HLS compiler back-end 110 is capable of selecting the timing information from either the variable timing library or the full case timing library having the smallest or minimum delay. HLS compiler back-end 110 is capable of comparing Delay A with Delay B and selecting the set of timing information corresponding to lower delay value of between Delay A and Delay B.

In block 316, HLS compiler back-end 110 uses the selected timing information for latency and delay estimation for performing scheduling of circuit design 112. It should be appreciated that the selected timing information will be the timing information selected in block 304 in the case of the sparsemux node having linear labels or the timing information selected in block 314 in the case where the sparsemux node has non-linear labels.

FIG. 4 illustrates an example of a data processing system 400 for use with the inventive arrangements in accordance with one or more embodiments of the disclosed technology. Data processing system 400 includes a hardware processor 402. Hardware processor 402 may be implemented as one or more hardware processors. Hardware processor 402 may be implemented as one or more circuits capable of executing computer-readable program instructions (program instructions). The circuit(s) may comprise integrated circuits (ICs) or may be embedded within an IC. In one or more examples, hardware processor 402 may be embodied as a central processing unit (CPU). Hardware processor 402 may include one or more cores, for example, where each core is capable of executing computer-readable program instructions. Hardware processor 402 may be implemented using any of a variety of architectures such as, for example, a complex instruction set computer architecture (CISC), a reduced instruction set computer architecture (RISC), a vector processing architecture, or other known architectures. For example, a hardware processor may be implemented using an x86 architecture (e.g., IA-32, IA-64), a Power Architecture, as an ARM processor, or the like.

Data processing system 400 can include memory 404. Memory 404 may be embodied as one or more computer-readable storage mediums. Memory 404 may include a volatile memory 406 and a non-volatile memory 408. Volatile memory 406 may be embodied as random-access memory (RAM) and may include cache memory. Volatile memory 406 may be referred to as “runtime memory.” Non-volatile memory 408 may include a non-volatile magnetic medium and/or a solid-state medium (typically called a “hard drive”). Non-volatile memory 408 also may include one or more disk drives capable of reading from and writing to various types of removable, non-volatile mediums such as a removable, non-volatile magnetic disk (e.g., a “floppy disk”) and/or a removable, non-volatile optical disk such as a CD-ROM, DVD-ROM or other optical media.

Memory 404 is capable of storing program instructions and/or data such that hardware processor 402 is capable of executing the program instructions to perform one or more operations as described within this disclosure. For example, the program instructions can include an operating system, one or more application programs, other program code, and program data. Processor 402, in executing the computer-readable program instructions, is capable of performing the various operations described herein that are attributable to a computer. In one or more examples, the program instructions may be embodied as one or more blocks or the entirety of framework 100 of FIG. 1.

Data processing system 400 may include one or more Input/Output (I/O) interfaces 410. I/O interface(s) 410 allow data processing system 400 to communicate with one or more external devices and/or communicate over one or more networks such as a local area network (LAN), a wide area network (WAN), and/or a public network (e.g., the Internet). Examples of I/O interfaces 410 may include, but are not limited to, network cards, modems, network adapters (wired and/or wireless), hardware controllers, etc. Examples of external devices also may include devices that allow a user to interact with data processing system 400 (e.g., a display, a keyboard, and/or a pointing device) and/or other devices such as accelerator card.

Bus 412 represents one or more of any of a variety of communication bus structures. By way of example, and not limitation, bus 412 may be implemented as a Peripheral Component Interconnect Express (PCIe) bus. Bus 412 couples to each of hardware processor 402, memory 404, and I/O interface(s) 410 through respective interface circuitry thereby allowing the devices to communicate. Bus 412 may represent a plurality of buses that may be interconnected and/or hierarchically organized.

Data processing system 400 is only one example implementation. Data processing system 400 can be practiced as a standalone device (e.g., as a user computing device or a server, as a bare metal server), in a cluster (e.g., two or more interconnected computers), or in a distributed cloud computing environment (e.g., as a cloud computing node) where tasks are performed by remote processing devices that are linked through a communications network. In a distributed cloud computing environment, program modules may be located in both local and remote computer system storage media including memory storage devices.

As used herein, the term “cloud computing” refers to a computing model that facilitates convenient, on-demand network access to a shared pool of configurable computing resources such as networks, servers, storage, applications, ICs (e.g., programmable ICs) and/or services. These computing resources may be rapidly provisioned and released with minimal management effort or service provider interaction. Cloud computing promotes availability and may be characterized by on-demand self-service, broad network access, resource pooling, rapid elasticity, and measured service.

The example of FIG. 4 is not intended to suggest any limitation as to the scope of use or functionality of example implementations described herein. Data processing system 400 is an example of computer hardware that is capable of performing the various operations described within this disclosure. In this regard, data processing system 400 may include fewer components than shown or additional components not illustrated in FIG. 4 depending upon the particular type of device and/or system that is implemented. The particular operating system and/or application(s) included may vary according to device and/or system type as may the types of I/O devices included. Further, one or more of the illustrative components may be incorporated into, or otherwise form a portion of, another component. For example, a processor may include at least some memory.

The terminology used herein is for the purpose of describing particular embodiments only and is not intended to be limiting. Notwithstanding, several definitions that apply throughout this document are expressly defined as follows.

As defined herein, the singular forms “a,” “an,” and “the” are intended to include the plural forms as well, unless the context clearly indicates otherwise.

As defined herein, the terms “at least one,” “one or more,” and “and/or,” are open-ended expressions that are both conjunctive and disjunctive in operation unless explicitly stated otherwise.

As defined herein, the term “automatically” means without human intervention.

As defined herein, the term “computer-readable storage medium” means a storage medium that contains or stores program instructions for use by or in connection with an instruction execution system, apparatus, or device. As defined herein, a “computer-readable storage medium” is not a transitory, propagating signal per se. The various forms of memory, as described herein, are examples of a computer-readable storage medium or two or more computer-readable storage mediums. A non-exhaustive list of examples of a computer-readable storage medium include an electronic storage device, a magnetic storage device, an optical storage device, an electromagnetic storage device, a semiconductor storage device, or any suitable combination of the foregoing. A non-exhaustive list of more specific examples of a computer-readable storage medium may include: a portable computer diskette, a hard disk, a RAM, a read-only memory (ROM), an erasable programmable read-only memory (EPROM or Flash memory), an electronically erasable programmable read-only memory (EEPROM), a static random-access memory (SRAM), a double-data rate synchronous dynamic RAM memory (DDR SDRAM or “DDR”), a portable compact disc read-only memory (CD-ROM), a digital versatile disk (DVD), a memory stick, a floppy disk, or the like.

As defined herein, “data processing system” means one or more hardware systems configured to process data, each hardware system including at least one hardware processor programmed to initiate operations and memory.

As defined herein, the phrase “in response to” and the phrase “responsive to” means responding or reacting readily to an action or event. The response or reaction is performed automatically. Thus, if a second action is performed “responsive to” a first action, there is a causal relationship between an occurrence of the first action and an occurrence of the second action. The term “responsive to” indicates the causal relationship.

The term “user” may refer to a human being.

As defined herein, the term “hardware processor” means at least one hardware circuit. The hardware circuit may be configured to carry out instructions contained in program code. The hardware circuit may be an integrated circuit. Examples of a hardware processor include, but are not limited to, a central processing unit (CPU), an array processor, a vector processor, a digital signal processor (DSP), a field-programmable gate array (FPGA), a programmable logic array (PLA), an application specific integrated circuit (ASIC), programmable logic circuitry, a controller, and a Graphics Processing Unit (GPU).

As defined herein, the terms “one embodiment,” “an embodiment,” “in one or more embodiments,” “in particular embodiments,” or similar language mean that a particular feature, structure, or characteristic described in connection with the embodiment is included in at least one embodiment described within this disclosure. Thus, appearances of the aforementioned phrases and/or similar language throughout this disclosure may, but do not necessarily, all refer to the same embodiment.

As defined herein, the term “substantially” means that the recited characteristic, parameter, or value need not be achieved exactly, but that deviations or variations, including for example, tolerances, measurement error, measurement accuracy limitations, and other factors known to those of skill in the art, may occur in amounts that do not preclude the effect the characteristic was intended to provide.

The terms first, second, etc. may be used herein to describe various elements. These elements should not be limited by these terms, as these terms are only used to distinguish one element from another unless stated otherwise or the context clearly indicates otherwise.

A computer program product may include a computer-readable storage medium (or mediums) having computer-readable program instructions thereon for causing a processor to carry out aspects of the inventive arrangements described herein. Within this disclosure, the terms “program code,” “program instructions,” and “computer-readable program instructions” are used interchangeably. Computer-readable program instructions described herein may be downloaded to respective computing/processing devices from a computer-readable storage medium or to an external computer or external storage device via a network, for example, the Internet, a LAN, a WAN and/or a wireless network. The network may include copper transmission cables, optical transmission fibers, wireless transmission, routers, firewalls, switches, gateway computers and/or edge devices including edge servers. A network adapter card or network interface in each computing/processing device receives program instructions from the network and forwards the computer-readable program instructions for storage in a computer-readable storage medium within the respective computing/processing device.

Program instructions for carrying out operations for the inventive arrangements described herein may be assembler instructions, instruction-set-architecture (ISA) instructions, machine instructions, machine dependent instructions, microcode, firmware instructions, or either source code or object code written in any combination of one or more programming languages, including an object-oriented programming language and/or procedural programming languages. Program instructions may include state-setting data. The program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a LAN or a WAN, or the connection may be made to an external computer (for example, through the Internet using an Internet Service Provider). In some cases, electronic circuitry including, for example, programmable logic circuitry, an FPGA, or a PLA may execute the program instructions by utilizing state information of the program instructions to personalize the electronic circuitry, in order to perform aspects of the inventive arrangements described herein.

Certain aspects of the inventive arrangements are described herein with reference to flowchart illustrations and/or block diagrams of methods, apparatus (systems), and computer program products. It will be understood that each block of the flowchart illustrations and/or block diagrams, and combinations of blocks in the flowchart illustrations and/or block diagrams, may be implemented by program instructions, e.g., program code.

These program instructions may be provided to a processor of a computer, special-purpose computer, or other programmable data processing apparatus to produce a machine, such that the program instructions, which execute via the processor of the computer or other programmable data processing apparatus, create means for implementing the functions/acts specified in the flowchart and/or block diagram block or blocks. These program instructions may also be stored in a computer-readable storage medium that can direct a computer, a programmable data processing apparatus, and/or other devices to function in a particular manner, such that the computer-readable storage medium having program instructions stored therein comprises an article of manufacture including program instructions which implement aspects of the operations specified in the flowchart and/or block diagram block or blocks.

The program instructions may also be loaded onto a computer, other programmable data processing apparatus, or other device to cause a series of operations to be performed on the computer, other programmable apparatus or other device to produce a computer implemented process, such that the program instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to various aspects of the inventive arrangements. In this regard, each block in the flowchart or block diagrams may represent a module, segment, or portion of instructions, which comprises one or more program instructions for implementing the specified operations.

In some alternative implementations, the operations noted in the blocks may occur out of the order noted in the figures. For example, two blocks shown in succession may be executed substantially concurrently, or the blocks may sometimes be executed in the reverse order, depending upon the functionality involved. In other examples, blocks may be performed generally in increasing numeric order while in still other examples, one or more blocks may be performed in varying order with the results being stored and utilized in subsequent or other blocks that do not immediately follow. It will also be noted that each block of the block diagrams and/or flowchart illustration, and combinations of blocks in the block diagrams and/or flowchart illustration, may be implemented by special purpose hardware-based systems that perform the specified functions or acts or carry out combinations of special purpose hardware and program instructions.

The descriptions of the various embodiments of the disclosed technology have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A method, comprising:
generating, using computer hardware, an intermediate representation of a design for an integrated circuit, wherein the design is specified in high-level programming language source code;
detecting, by the computer hardware, selected logic within the intermediate representation and converting the selected logic into a sparsemux node;
choosing, by the computer hardware, a selected core from a plurality of cores to implement the sparsemux node based on a label encoding format and a default input of the sparsemux node; and
generating, by the computer hardware, a circuit design, wherein one or more operations of the selected core are scheduled based on a timing model corresponding to the selected core.

2. The method of claim 1, further comprising:
selecting the timing model for the selected core from a plurality of timing models based, at least in part, on the label encoding format.

3. The method of claim 1, wherein the selected logic includes a phi node.

4. The method of claim 1, wherein the generating the intermediate representation includes translating a high-level programming language sparsemux statement into an intermediate representation sparsemux node.

5. The method of claim 1, wherein the selected logic merges a plurality of control flow paths and selects a value from a plurality of values based on a selected control flow path of the plurality of control flow paths taken.

6. The method of claim 1, wherein the sparsemux node specifies a selector value defining a single static assignment value that indicates a case to select.

7. The method of claim 6, wherein the sparsemux node specifies a default value defining the single static assignment value for a default case.

8. The method of claim 7, wherein the sparsemux node specifies a plurality of case labels each defining a case, wherein a particular case label of the plurality of case labels is selected based on the selector value.

9. The method of claim 8, wherein the sparsemux node specifies one or more case values each defining a single static assignment value used as a result for the particular case label that is selected.

10. A system, comprising:
a computer-readable storage medium having program instructions stored thereon; and
a hardware processor capable of executing the program instructions to perform operations comprising:
generating an intermediate representation of a design for an integrated circuit, wherein the design is specified in high-level programming language source code;
detecting selected logic within the intermediate representation and converting the selected logic into a sparsemux node;
choosing a selected core from a plurality of cores to implement the sparsemux node based on a label encoding format and a default input of the sparsemux node; and
generating a scheduled circuit design, wherein one or more operations of the selected core are scheduled based on a timing model corresponding to the selected core.

11. The system of claim 10, further comprising:
selecting the timing model for the selected core from a plurality of timing models based, at least in part, on the label encoding format.

12. The system of claim 10, wherein the selected logic includes a phi node.

13. The system of claim 10, wherein the generating the intermediate representation includes translating a high-level programming language sparsemux statement into an intermediate representation sparsemux node.

14. The system of claim 10, wherein the selected logic merges a plurality of control flow paths and selects a value from a plurality of values based on a selected control flow path of the plurality of control flow paths taken.

15. The system of claim 10, wherein the sparsemux node specifies a selector value defining a single static assignment value that indicates a case to select.

16. The system of claim 15, wherein the sparsemux node specifies a default value defining the single static assignment value for a default case.

17. The system of claim 16, wherein the sparsemux node specifies a plurality of case labels each defining a case, wherein a particular case label of the plurality of case labels is selected based on the selector value.

18. The system of claim 17, wherein the sparsemux node specifies one or more case values each defining a single static assignment value used as a result for the particular case label that is selected.

19. A computer program product comprising a computer readable storage medium having program instructions embodied therewith, wherein the program instructions are executable by computer hardware to cause the computer hardware to initiate executable operations comprising:
generating an intermediate representation of a design for an integrated circuit, wherein the design is specified in high-level programming language source code;
detecting selected logic within the intermediate representation and converting the selected logic into a sparsemux node;
choosing a selected core from a plurality of cores to implement the sparsemux node based on a label encoding format and a default input of the sparsemux node; and
generating a scheduled circuit design, wherein one or more operations of the selected core are scheduled based on a timing model corresponding to the selected core.

20. The computer program product of claim 19, wherein the program instructions are executable by the computer hardware to initiate operations further comprising:
selecting the timing model for the selected core from a plurality of timing models based, at least in part, on the label encoding format.
